(19) United States
(12) Patent Application Publication
(10) Pub. No.: US 2008/0042748 A1
(43) Pub. Date: Feb. 21, 2008

(54) DB-LINEAR VARIABLE VOLTAGE GAIN AMPLIFIER

(76) Inventors: Nyun-Tae Kim, Yongin-si (KR); Jong-Jae Ruy, Suwon-si (KR)

Correspondence Address: F. CHAU & ASSOCIATES, LLC, 130 WOODBURY ROAD, WOODBURY, NY, 11797, US

(21) Appl. No.: 11/782,720

(22) Filed: Jul. 25, 2007

(30) Foreign Application Priority Data
Aug. 18, 2006 (KR) 2006-78290

(51) Int. Cl. H03G 1/00

(52) U.S. Cl. 330/254

(57) ABSTRACT

A variable voltage gain amplifier in an automatic voltage gain control circuit includes a denominator current source that generates a denominator current corresponding to a denominator a numerator current source that generates a numerator current corresponding to a numerator, and a differential amplifier that amplifies an input voltage with a variable voltage gain and generates an output voltage that is substantially dB-linear with the input voltage when the variable voltage gain that is expressed as an exponential function of a control voltage is approximated to a fraction where each of a denominator and a numerator is expressed as a third order polynomial function of the control voltage.

### CROSS-REFERENCE TO RELATED APPLICATIONS

This application claims priority, under 35 USC § 119 of Korean Patent Application No. 2006-78290 filed on Aug. 18, 2006 in the Korean Intellectual Property Office (KIPO), which is incorporated by reference herein in its entirety.

### BACKGROUND OF THE INVENTION

1. Field of the Invention

The present invention relates to controlling a voltage gain, and more particularly to a method of varying a voltage gain, a variable voltage gain amplifier, and an automatic voltage gain control circuit including the variable voltage gain amplifier.

2. Description of the Related Art

An automatic voltage gain control (AGC) circuit controls the amplitude of an input signal in advance at a front part of a signal processing circuit in order to maintain the amplitude of the input signal in a dynamic range of the signal processing circuit that processes the input signal or in order to cause the input signal to have an amplitude corresponding to a specification. For example, the automatic voltage gain control circuit may be used for controlling the amplitude of the input signal in order to prevent saturation of an output signal when processing an analog voice signal and an analog image signal in an analog circuit. The automatic voltage gain control circuit may also be used for amplifying an input digital signal according to the specification when the input digital signal is attenuated through several channels.

FIG. 1 is a block diagram of a conventional automatic voltage gain control circuit.

Referring to FIG. 1, the conventional automatic voltage gain control circuit 10 includes a variable voltage gain amplifier 11, an amplitude detector 12, a differential amplifier 13, and a low pass filter 14.

The variable voltage gain amplifier 11 amplifies an input signal with a voltage gain that varies responding to an AGC control signal. The amplitude to detector 12 detects the amplitude of an output signal of the variable voltage gain amplifier 11. The differential amplifier 13 amplifies a difference between the output of the amplitude detector 12 and a reference signal Vref, and outputs the AGC signal. The low pass filter 14 removes a high frequency noise in the AGO signal, and thus the low pass filter 14 prevents the voltage gain from being varied due to the high frequency noise.

An automatic voltage gain control circuit including a variable voltage gain amplifier can increase the voltage gain of an amplifier when the amplitude of an input signal becomes lower, and can decrease the voltage gain of the amplifier when the amplitude of the input signal becomes higher by using the included variable voltage gain amplifier. The term “settling time,” is refers to a time for a voltage gain to reach a target value. Since an efficiency of a device using the automatic voltage gain control circuit is determined by the longest settling time of the automatic voltage gain control circuit, the settling time needs to be maintained even though the voltage gain is changed.

A decibel (dB) value of the variable voltage gain amplifier needs to be linear over its intended range so that the settling time may be maintained regardless of the voltage gain. In other words, the voltage gain needs to have features close to exponential function features.

In a bipolar junction transistor (BJT), a collector current has an exponential relation to the voltage between its base and emitter. Thus, a variable voltage gain amplifier of a conventional art uses the features of the BJT.

When implementing a variable voltage gain amplifier by complementary metal oxide semiconductor (CMOS) fabrication, implementing dB-linear features is difficult because of features of the MOS transistor. In the MOS transistor, depending on an operation mode, a source current (into the source of the MOS transistor) may be proportional to the difference between its threshold voltage and the voltage between its source and gate, or the source current may be proportional to the square of the difference between the threshold voltage and the voltage between the source and the gate.

In conventional art, an exponential function is approximated to a fraction where each of a numerator and a denominator is expressed as a first order polynomial expression as Expression A and circuits where a voltage-current relation of a MOS transistor is expressed as the first order polynomial expression are used.

$${e}^{- 2 x} = \frac{1 - x}{1 + x} \qquad [ Expression A ]$$

However, the MOS transistor only has the voltage-current relation that is expressed as the first order polynomial function such as Expression A only when the MOS transistor operates in a triode mode. Thus, the MOS transistor does not have features of an exponential function in a broad range of a voltage.

### SUMMARY OF THE INVENTION

An aspect of the present invention provides a method of varying a voltage gain by using a third order polynomial function approximated from an exponential function.

Another aspect of the present invention provides a variable voltage gain to amplifier that varies a voltage gain by using a third order polynomial function approximating an exponential function.

Other aspects of the present invention provide an automatic voltage gain control circuit including the variable voltage gain amplifier.

Typically, a voltage gain of a variable voltage gain amplifier is expressed as a proportion between the voltage of an input signal and the voltage of an output signal. If the voltage gain has dB-linear features, the voltage gain can be expressed as an exponential function of a control voltage of an automatic voltage gain control (AGO) signal. When Vc denotes the control voltage of the AGC signal and 2a, denotes a coefficient ratio, the voltage gain can be expressed as Expression B,

$$Gain = \frac{Vout}{Vin} = Exp ( 2 a \times Vc ) , \qquad [ Expression B ]$$

a is usually less than 1; and an exponential function of Vc can be approximated to a third order polynomial function of Vc as in Expression C.

$$Exp ( a \times Vc ) \approx 1 + a \times Vc + \frac{{a}^{2}}{2} \times {Vc}^{2} + \frac{{a}^{3}}{6} \times {Vc}^{3} \qquad [ Expression C ]$$

When Expression C is applied to Expression B, the voltage gain can be approximately expressed as in Expression D.

$$Gain = \frac{Exp ( a \times Vc )}{Exp ( - a \times Vc )} \approx \frac{1 + a \times Vc + \frac{{a}^{2}}{2} \times {Vc}^{2} + \frac{{a}^{3}}{6} \times {Vc}^{3}}{1 - a \times Vc + \frac{{a}^{2}}{2} \times {Vc}^{2} - \frac{{a}^{3}}{6} \times {Vc}^{3}} \qquad [ Expression D ]$$

Expression D can be transformed into Expression E.

$$Gain = \frac{Exp ( a \times Vc )}{Exp ( - a \times Vc )} \approx \frac{Vc \times ( \frac{1}{Vc} + a + \frac{{a}^{2}}{2} \times Vc + \frac{{a}^{3}}{6} \times {Vc}^{2} )}{Vc \times ( \frac{1}{Vc} - a + \frac{{a}^{2}}{2} \times Vc - \frac{{a}^{3}}{6} \times {Vc}^{2} )} \qquad [ Expression E ]$$

In order to use features of the saturation mode of a metal oxide semiconductor (MOS) transistor; such as a relation between a voltage and a current, the denominator of Expression E can be transformed into Expression F.

$$\frac{1}{Vc} - a + \frac{{a}^{2}}{2} \times Vc - \frac{{a}^{3}}{6} \times {Vc}^{2} = \frac{1}{Vc} - \frac{3}{8} \times a \times {( 1 - \frac{2}{3} \times a \times Vc )}^{2} - \frac{5}{8} \times a \qquad [ Expression F ]$$

Referring to Expression F, the first term

$$\frac{1}{Vc}$$

can be implemented by using an analog divider. The second term

$$- \frac{3}{8} \times a \times {( 1 - \frac{2}{3} \times a \times Vc )}^{2}$$

can be implemented by using features of a relation between the voltage and the current in the saturation mode of a MOS transistor. The third term

$$- \frac{5}{8} \times a$$

can be implemented by using a voltage source that generates a fixed voltage or a current source that generates a fixed current.

Also, the numerator of Expression E can be transformed into Expression G.

$$\frac{1}{Vc} + a + \frac{{a}^{2}}{2} \times Vc + \frac{{a}^{3}}{6} \times {Vc}^{2} = \frac{1}{Vc} + \frac{3}{8} \times a \times {( 1 - \frac{2}{3} \times a \times Vc )}^{2} + \frac{5}{8} \times a \qquad [ Expression G ]$$

The voltage gain of the variable voltage gain amplifier can be approximately expressed as Expression H by using Expression F and Expression G.

$$Gain = \frac{Exp ( a \times Vc )}{Exp ( - a \times Vc )} = Exp ( 2 aVc ) \approx \frac{\frac{1}{Vc} + \frac{3}{8} \times a \times {( 1 + \frac{2}{3} \times a \times Vc )}^{2} + \frac{5}{8} \times a}{\frac{1}{Vc} - \frac{3}{8} \times a \times {( 1 - \frac{2}{3} \times a \times Vc )}^{2} - \frac{5}{8} \times a} \qquad [ Expression H ]$$

Therefore a variable voltage gain amplifier that has a voltage gain of dB-linear features and an automatic voltage gain control circuit that includes the variable voltage gain amplifier can be implemented by using Expression H. In addition, each term of Expression H can be implemented by using a current generator and an amplifier implemented with MOS transistors. The current generator provides currents, and the amplifier has a voltage gain expressed as a proportion of the currents.

In some exemplary embodiments of the present invention, a method of varying a voltage gain includes approximating a variable voltage gain that is expressed as an exponential function of a control voltage as a fraction where each of a denominator and a numerator is expressed as a third order polynomial function of the control voltage, generating a numerator current corresponding to the numerator and a denominator current corresponding to the denominator, amplifying an input voltage with the variable voltage gain expressed as the fraction, and generating an output voltage that is substantially dB-linear with the input voltage.

The generating of the numerator current and the denominator current may include transforming the third order polynomial function of the numerator and the denominator to a function of the control voltage that includes an inversed first order polynomial term, a first order polynomial term, and a second order polynomial term, and generating a current corresponding to each of the inversed first order polynomial term, the first order polynomial term, and the second order polynomial term after transforming.

generating the numerator current and the denominator current may include approximating the variable voltage gain as the fraction in Expression 1 where a denotes a coefficient ratio of the variable voltage gain, and Vc denotes the control voltage.

$$Gain = Exp ( 2 aVc ) \approx \frac{1 / Vc + 3 / 8 a \times {( 1 + 2 / 3 a \times Vc )}^{2} + 5 / 8 a}{1 / Vc - 3 / 8 a \times {( 1 - 2 / 3 a \times Vc )}^{2} - 5 / 8 a} \qquad [ Expression 1 ]$$

generating the numerator current and the denominator current may include generating a first inverse proportion current corresponding to the first term of the denominator and a second inverse proportion current corresponding to the first term of the numerator by using an analog divider, generating a first square current corresponding to the second term of the denominator and a second square current corresponding to the second term of the numerator by using a metal oxide semiconductor (MOS) transistor, generating a first constant current corresponding to the third term of the denominator and a second constant current corresponding to the third term of the numerator by using a current source, generating the denominator current by summing the first square current and the first constant current, subtracting the sum from the first inverse proportion current, and generating the numerator current by summing the second inverse proportion current, the second square current and the second constant current.

Each of the input voltage and the output voltage may be a differential to signal.

In some exemplary embodiments of the present invention, a variable voltage gain amplifier includes the denominator current source, the numerator current source, and a differential amplifier. The denominator current source that generates a denominator current corresponding to the denominator when a variable voltage gain that is expressed as an exponential function of a control voltage is approximated to a fraction where each of a denominator and a numerator is expressed as a third order polynomial function of the control voltage. The numerator current source that generates a numerator current corresponding to the numerator when a variable voltage gain that is expressed as an exponential function of a control voltage is approximated to a fraction where each of a denominator and a numerator is expressed as a third order polynomial function of the control voltage. The differential amplifier that amplifies an input voltage with the variable voltage gain expressed as the fraction and generates an output voltage that is substantially dB-linear with the input voltage.

When the third order polynomial expression of the numerator and the denominator is transformed to a function of the control voltage that includes an inversed first order polynomial term, a first order polynomial term and a second order polynomial term, the numerator current source and the denominator current source may generate a current corresponding to each of the inversed first order polynomial term, the first order polynomial term and the second order polynomial term after transforming.

The denominator current source and the numerator current source may generate the denominator current and the numerator current corresponding to the denominator and the numerator in Expression 1 where a denotes a coefficient ratio and Vc denotes the control voltage.

$$Gain = Exp ( 2 aVc ) \approx \frac{1 / Vc + 3 / 8 a \times {( 1 + 2 / 3 a \times Vc )}^{2} + 5 / 8 a}{1 / Vc - 3 / 8 a \times {( 1 - 2 / 3 a \times Vc )}^{2} - 5 / 8 a} \qquad [ Expression 1 ]$$

The denominator current source may include a first inverse proportion current generator that generates a first inverse proportion current corresponding to a first term of the denominator in expression 1, a first square current generator that generates a first square current corresponding to a second term of the denominator in expression 1, a first constant current generator that generates a first constant current corresponding to a third term of the denominator in expression 1, and a first summation unit that sums the first square current and the first constant current, subtracts the sum from the first inverse proportion current and generates the denominator current.

The first inverse proportion current generator may include an analog divider that receives the control voltage and outputs a current that has an inversed value of the control voltage.

The first square current generator may include a P-type metal oxide semiconductor (PMOS) transistor where a voltage of ⅔×Vc is applied to its gate terminal, a supply voltage is applied at its source terminal and the first square current is outputted at its drain terminal, and the PMOS transistor is implemented while satisfying Expression 2 where Kp denotes a process parameter of the PMOS transistor, Vth denotes the threshold voltage of the PMOS transistor, Vdd denotes the supply voltage, and a denotes a coefficient ratio of the variable voltage gain.

$$Kp = \frac{3 / 8 a}{{( Vdd - Vth )}^{2}} , a = \frac{1}{( Vdd - Vth )} \qquad [ Expression 2 ]$$

The numerator current source may include a second inverse proportion current generator that generates a second inverse proportion current corresponding to a first term of the numerator in Expression 1, a second square current generator that generates a second square current corresponding to a second term of the numerator in Expression 1, a second constant current generator that generates a second constant current corresponding to a third term of the numerator in Expression 1, and a second summation unit that sums the second inverse proportion current the second square current and the second constant current, and generates the numerator current.

The second inverse proportion current generator may include an analog divider that receives the control voltage and outputs a current that has an inversed value of the control voltage.

The second square current generator may include a N-type metal oxide semiconductor (NMOS) transistor where a voltage of ⅔×Vc is applied through a gate terminal, a supply voltage is applied through a source terminal and the second square current is outputted through a drain terminal, and the NMOS transistor is implemented while satisfying Expression 3 where Kn denotes a process parameter of the NMOS transistor, Vth denotes the threshold voltage of the NMOS transistor, Vss denotes the supply voltage, and a denotes a coefficient ratio of the variable voltage gain.

$$Kn = \frac{3 / 8 a}{{( - Vss - Vth )}^{2}} , a = \frac{1}{( - Vss - Vth )} \qquad [ Expression 3 ]$$

Each of the input voltage and the output voltage may be a differential signal.

The differential amplifier may include a first metal oxide semiconductor (MOS) transistor differential pair that is diode-connected respectively and is biased by the denominator current, a second MOS transistor differential pair that receives the input voltage through their gate terminals, is biased by the numerator current, is coupled to the first MOS transistor differential pair through both drain terminals, and outputs the output voltage through their drain terminals.

In some exemplary embodiments of the present invention, an automatic voltage gain control circuit includes a variable voltage gain amplifier that generates an output voltage that is an amplified voltage of an input voltage with a variable voltage gain responding to a control voltage, an amplitude detector that detects an amplitude of the output voltage, and a differential amplifier that compares the detected amplitude of the output voltage with an amplitude of a reference signal, and generates a control voltage. The variable voltage gain amplifier includes a denominator current source that generates a denominator current corresponding to the denominator when a variable voltage gain that is to expressed as an exponential function of a control voltage is approximated as a fraction where each of a denominator and a numerator is expressed as a third order polynomial function of the control voltage, a numerator current source that generates a numerator current corresponding to the numerator, and a differential amplifier that amplifies the input voltage with the variable voltage gain expressed as the fraction and generates an output voltage that is substantially dB-linear with the input voltage.

When the third order polynomial expression of the numerator and the denominator is transformed to a function of the control voltage that includes an inversed first order polynomial term, a first order polynomial term, and a second order polynomial term, the numerator current generator and the denominator current generator may generate a current corresponding to each of the inversed first order polynomial term, the first order polynomial term, and the second order polynomial term after transforming.

The denominator current source and the numerator current source may generate the denominator current and the numerator current corresponding to the denominator and the numerator in Expression 1 where a denotes a coefficient ratio and Vc denotes the control voltage.

$$Gain = Exp ( 2 aVc ) \approx \frac{1 / Vc + 3 / 8 a \times {( 1 + 2 / 3 a \times Vc )}^{2} + 5 / 8 a}{1 / Vc - 3 / 8 a \times {( 1 - 2 / 3 a \times Vc )}^{2} - 5 / 8 a} \qquad [ Expression 1 ]$$

The denominator current source may include a first inverse proportion current generator that generates a first inverse proportion current corresponding to the first term of the denominator in Expression 1, a first square current generator that generates a first square current corresponding to the second term of the denominator in Expression 1, a first constant current generator that generates a first constant current corresponding to the third term of the denominator in Expression 1, and a first summation unit (e.g. current mirror) that sums the first square current and the first constant current, subtracts the sum from the first inverse proportion current, and thereby generates the denominator current.

The first inverse proportion current generator may include an analog divider that receives the control voltage, and outputs a current that has an inversed value of the control voltage.

The first square current generator may include a PMOS transistor where a voltage of ⅔×Vc is applied to its gate terminal, a supply voltage is applied to its source terminal, and the first square current is outputted through its drain terminal, and the PMOS transistor is implemented while satisfying Expression 2 where Kp denotes a process parameter of the PMOS transistor, Vth denotes the threshold voltage of the PMOS transistor, Vdd denotes the supply voltage and a denotes a coefficient ratio of the variable voltage gain.

$$Kp = \frac{3 / 8 a}{{( Vdd - Vth )}^{2}} , a = \frac{1}{( Vdd - Vth )} \qquad [ Expression 2 ]$$

The numerator current source may include a second inverse proportion current generator that generates a second inverse proportion current corresponding to the first term of the numerator in Expression 1 a second square current generator that generates a second square current corresponding to the second term of the numerator in Expression 1, a second constant current generator that generates a second constant current corresponding to the third term of the numerator in Expression 1, and a second summation unit that sums the second inverse proportion current, the second square current, and the second constant current, and generates the numerator current.

The second inverse proportion current generator may include an analog divider that receives the control voltage, and outputs a current that has an inversed value of the control voltage.

The second square current generator may include a NMOS transistor where a voltage of ⅔×Vc is applied to its gate terminal, a supply voltage is applied to its source terminal, and the second square current is outputted at its drain terminal, and the NMOS transistor is implemented while satisfying Expression 3 where Kn denotes a process parameter of the NMOS transistor, Vth denotes the threshold voltage of the NMOS transistor, Vss denotes the supply voltage, and a denotes a coefficient ratio of the variable voltage gain.

$$Kn = \frac{3 / 8 a}{{( - Vss - Vth )}^{2}} , a = \frac{1}{( - Vss - Vth )} \qquad [ Expression 3 ]$$

Each of the input voltage and the output voltage may be a differential signal.

The differential amplifier may include a first differential pair of diode-connected MOS transistors that are biased by the denominator current, and a second differential pair of MOS transistors that receive the differential input voltage through their gate terminals, are biased by the numerator current, and are coupled to a corresponding one of the first MOS transistor differential pair through their respective drain terminals, and outputs the output voltage through their coupled drain terminals.

Therefore, accordingly a method of varying a voltage gain, a variable voltage gain amplifier, and an automatic voltage gain control circuit can have a variable voltage gain that is substantially dB-linear with a control voltage of a broad range.

Embodiments of the present invention now will be described more fully with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any to and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments and is not intended to be limiting of the invention. As used herein, the singular forms “a,” “an” and “the” are intended to include the plural forms as well, unless the context clearly indicates otherwise.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a block diagram of a conventional automatic voltage gain control circuit;

FIG. 2 is a block diagram of a variable voltage gain amplifier according to an exemplary embodiment of the present invention;

FIG. 3 is a circuit diagram of the denominator current source 21 shown in FIG. 2;

FIG. 4 is a circuit diagram of a variable voltage gain amplifier according to another exemplary embodiment of the present invention;

FIG. 5A is a graph illustrating dB-linear features of a conventional differential amplifier performing approximation by using a first order polynomial expression; and

FIG. 5B is a graph illustrating dB-linear features of a differential amplifier in case of approximation by using a third order polynomial expression according to an exemplary embodiment of the present invention.

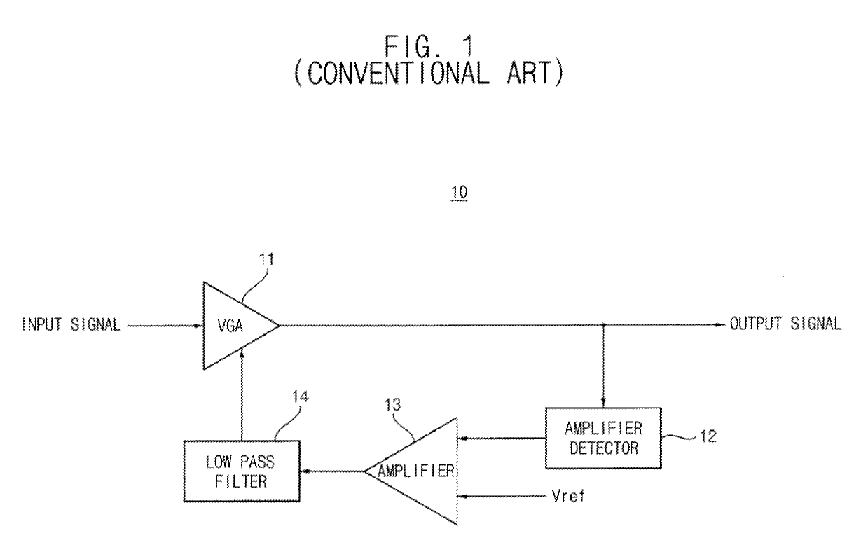

### DETAILED DESCRIPTION OF THE EXEMPLARY EMBODIMENTS OF THE INVENTION

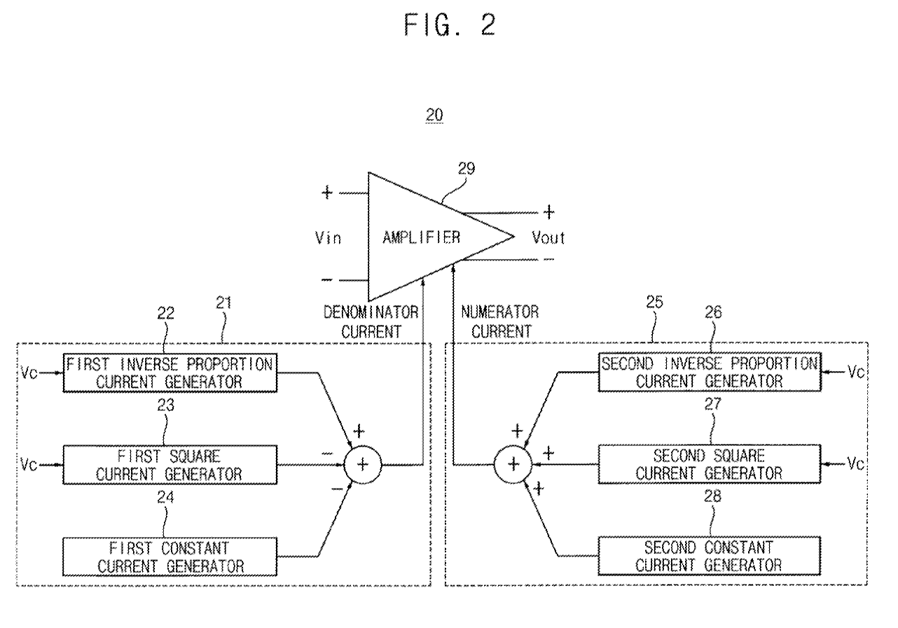

FIG. 2 is a block diagram of a variable voltage gain amplifier according to an exemplary embodiment of the present invention.

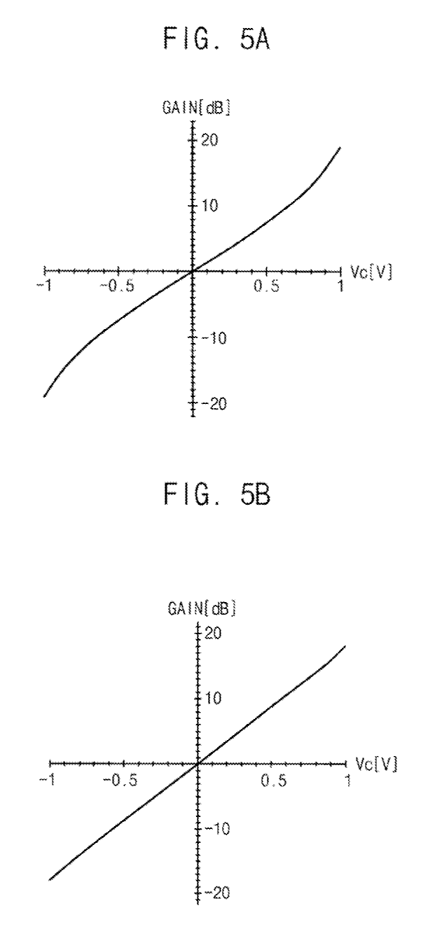

Referring to FIG. 2, the variable voltage gain amplifier 20 includes a denominator current source 21, a numerator current source 25, and a differential amplifier 29. The variable voltage gain amplifier 20 receives a differential input signal Vin (Vin+ and Vin−) and generates a differential output signal Vout (Vout+ and Vout−) that is an amplified copy of the input signal Vin. The variable voltage gain amplifier 20 has a voltage gain that is substantially dB-linear with a control voltage Vc (see FIGS. 5A and 5B).

The denominator current source 21 generates a denominator current IC1 that is expressed in Expression F. The denominator current source 21 includes a first inverse proportion current generator 22, a first square current generator 23 and a first constant current generator 24. The first inverse proportion current generator 22 generates an inverse proportion current that has inverse to proportional relation with the control voltage Vc. The first square current generator 23 generates a square current that has square relation with the control voltage Vc, The first constant current generator 24 generates a first constant current.

The numerator current source 25 generates a numerator current IC2 that is expressed in Expression G. The numerator current source 25 includes a second inverse proportion current generator 26, a second square current generator 27, and a second constant current generator 28. The second inverse proportion current generator 26 generates an inverse proportion current that has inverse proportional relation with the control voltage Vc. The second square current generator 27 generates a square current that has square relation with the control voltage Vc. The second constant current generator 24 generates a second constant current.

The differential amplifier 29 amplifies an input differential signal Vin (Vin+ and Vin−) with a voltage gain that is expressed as the ratio between the denominator current IC1 and the numerator current IC2, and outputs an output differential signal Vout (Vout+ and Vout−).

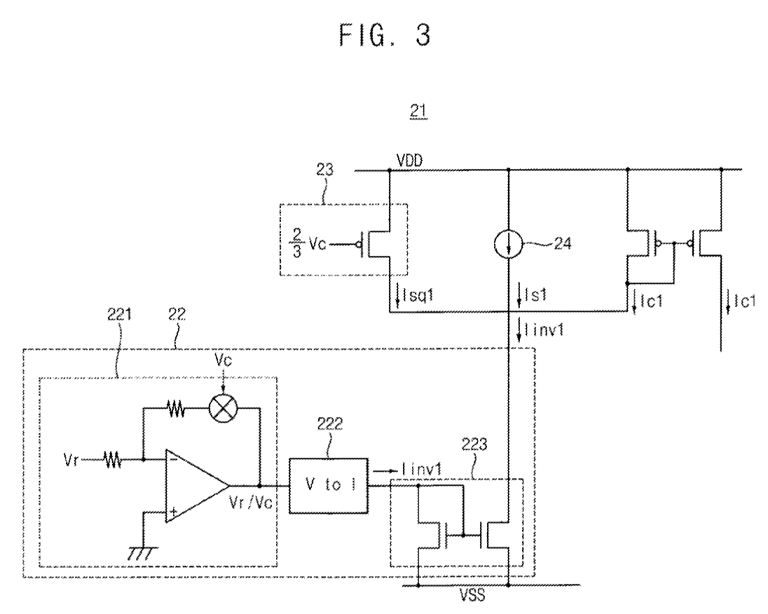

FIG. 3 is a circuit diagram of the denominator current source 21 shown in FIG. 2.

Hereinafter the operation of the denominator current source 21 will be described with reference to FIG. 3.

The first inverse proportion current generator 22 in the denominator current source 21 generates a current related to the first term of Expression F by using an analog divider 221, a voltage-to-current converter 222, and a current to mirror 223, The analog divider 221 receives a reference voltage Vr and a control voltage Vc, and outputs a voltage expressed as

$$\frac{Vr}{Vc} .$$

The analog divider 221 generates an output voltage (Vr/Vc) that is proportional to a ratio between two input voltages Vr and Vc. Thus, if the reference voltage Vr is 1 (V), the voltage expressed as

$$\frac{Vr}{Vc}$$

becomes an inverse proportion voltage expressed as

$$\frac{1}{Vc} .$$

### The inverse proportion voltage expressed as

$$\frac{1}{Vc}$$

converted to a current in the voltage-to-current converter 222. The current is outputted as a first inverse proportion current linv1 through the current mirror 223. Therefore, the first inverse proportion current linv1 has an inverse relation with the control voltage Vc.

The first square current generator 23 generates a square current Isq1 by using a MOS transistor. The square current Isq1 is related to a second term of Expression F. The third term of Expression F] can be transformed into Expression I.

$$\frac{3}{8} \times a \times {( 1 + \frac{2}{3} \times a \times Vc )}^{2} = \frac{3}{8} \times a \times {a}^{2} \times {( \frac{1}{a} + \frac{2}{3} \times Vc )}^{2} \qquad [ Expression l ]$$

When the PMOS transistor operates in a saturation mode, its drain current is proportional to the square of the difference between its threshold voltage and the voltage between its gate and its source (Vgs). For example, the drain current of a PMOS transistor can be expressed as Expression J.

$$\begin{matrix}Id = \frac{1}{2} \times μ p \times Cox \times \frac{W}{L} \times {( Vs - Vg - Vth )}^{2} \\ = Kp \times {( Vg - ( Vs - Vth ) )}^{2}\end{matrix} \qquad [ Expression J ]$$

In Expression J, μp denotes its hole-mobility, Cox denotes the capacitance of its oxide per unit area, W, denotes the width of its gate, L denotes the length of its gate, 1 denotes the voltage at its gate terminal, Vs denotes the voltage at its source terminal, Vth denotes its threshold voltage, and Kp denotes a parameter of the PMOS transistor. The Kp can be determined by a designer by adjusting W and L. If the source terminal of the PMOS transistor is connected to the supply voltage Vdd and the features of the PMOS transistor satisfies Expression K, the current of Expression J can be expressed as Expression I.

$$Kp = \frac{\frac{3}{8} \times a}{{( Vdd - Vth )}^{2}} , a = \frac{1}{Vdd - Vth} \qquad [ Expression K ]$$

Referring to Expression K, the first square current generator 23 can generate a current related to a second term of Expression F by using a PMOS transistor. The PMOS transistor has Kp, Vdd, and Vth that are determined by a. In the PMOS transistor, the voltage between its gate and its source is

$$\frac{2}{3}$$

times the control voltage Vc. The current generated by the PMOS transistor can be expressed as Expression L.

$$\begin{matrix}Imp = Kp \times {( \frac{2}{3} \times Vc - Vdd + Vth )}^{2} \\ = \frac{3}{8} \times a \times {( 1 - \frac{2}{3} \times a \times Vc )}^{2}\end{matrix} \qquad [ Expression L ]$$

The first constant current generator 24 generates a constant current Is1 that is related to the third term of Expression F.

The denominator current source 21 sums (adds together) the first square current Isq1 (generated by the first square current generator 23) and the first in constant current Is1 (generated by the first constant current generator 24), and subtracts that sum from the first inverse proportion current linv1 (generated by the first inverse proportion current generator 22), and outputs the difference as denominator current IC1 (through a current mirror) as shown in FIGS. 2 and 3.

The numerator current source 25 may be constructed by substantially as the mirror of current source architecture of the denominator current source 21 by using an NMOS transistor. Thus, a redundant description of the implementation of the numerator current source 25 will be omitted. In the NMOS transistor of the numerator current source 25, Kn has same value as Kp, the Vss that is connected to its source terminal has same value as −Vdd, and the absolute value of its threshold voltage is equal to the threshold voltage of the PMOS transistor of the denominator current source 21. The numerator current source 25 sums (adds together) the second inverse proportion current linv2 (generated by the second inverse proportion current generator 26), the second square current Isq2 (generated by the second square current generator 27) and the second constant current Is2 (generated by the second constant current generator 28), and outputs the sum as numerator current IC2 (through a current mirror) as shown in FIG. 2.

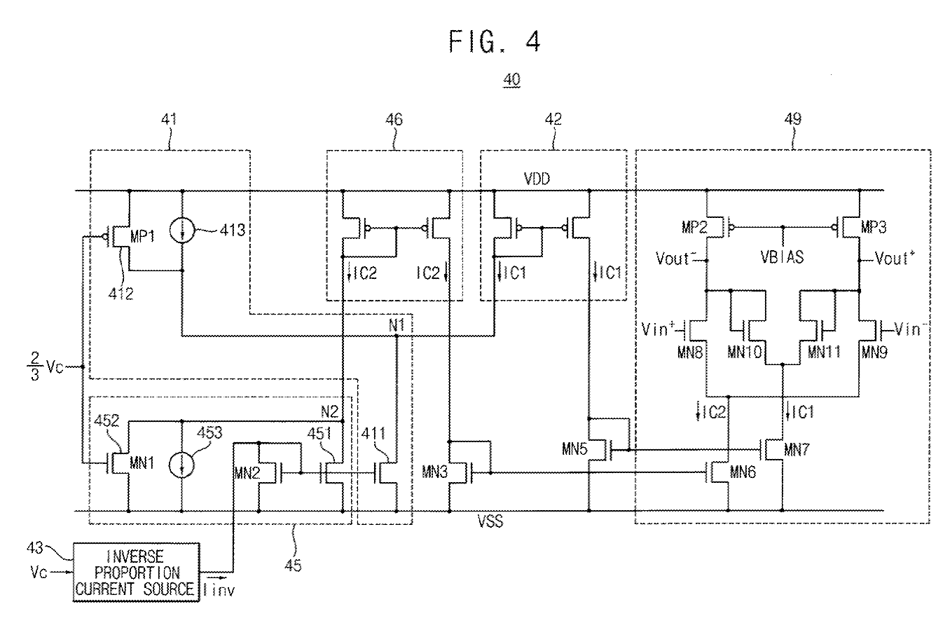

FIG. 4 is a circuit diagram of a variable voltage gain amplifier according to another exemplary embodiment of the present invention.

Referring to FIG. 4, the variable voltage gain amplifier 40 includes a denominator current source (41 with current mirror 42), a numerator current source (45 with current mirror 46), both sharing one inverse proportion current to source 43 (see 22 in FIG. 3), and a differential amplifier 49.

The denominator current source 41 includes a first inverse proportion current generator 411, a first square current generator 412, and a first constant current generator 413. A first current mirror 42 mirrors the current that is internally generated at node N1 of the denominator current source 41, and outputs the mirrored current as denominator current IC1. The denominator current IC1 is mirrored to the differential amplifier 49 by a fifth NMOS transistor MN5 and a seventh NMOS transistor MN7.

The first inverse proportion current generator 411 (among a current mirror's transistors MN2, 451 and 411) mirrors the inverse proportion current linv generated by a shared inverse proportion current source 43, and the current mirror comprised of transistors MN2, 451 and 411 outputs to each of the denominator current source 41 and the numerator current source 45 a first inverse proportion current related to a first term of Expression F. The inverse proportion current source 43 may include an analog divider 221 and a voltage-to-current converter 222 as illustrated in the inverse proportion current generator 22 shown in FIG. 3.

The first square current generator (e.g., saturation mode PMOS transistor MP1) 412 includes a first PMOS transistor MP1. A voltage

$$\frac{2}{3} \times Vc$$

is applied to the gate terminal of the first PMOS transistor MP1 and a first square current related to a second term of Expression F is outputted through its drain terminal.

The first constant current generator 413 generates a first constant current related to a third term of Expression F.

The first square current (from 412) and the first constant current (from 413) are added together at first node N1 and the first inverse proportion current (from 43 and 451) is subtracted from the first node N1, and the summation output current (the difference) is applied to the first current mirror 42 and output as denominator current IC1.

The numerator current source 45 includes a second inverse proportion current generator 451 (among a current mirror's transistors MN2, 451 and 411), a second square current generator 452 (e.g., NMOS transistor MN1), and a second constant current generator 453. A second current mirror 46 mirrors the current that internally generated at node N2 of the numerator current source 45′ and outputs the mirrored current as numerator current IC2. The numerator current IC2 is mirrored to the differential amplifier 49 by a third NMOS transistor MN3 and a sixth NMOS transistor MN6.

The second inverse proportion current generator 451 mirrors the inverse proportion current linv generated by the inverse proportion current source 43, and outputs a second inverse proportion current related to a first term of Expression G to the numerator current source 45. The current mirror comprising the second inverse proportion current generator 451 and the inverse proportion current generator 451, can mirror the inverse proportion current linv in common with the first inverse proportion current generator 411. In alternative embodiments, the second inverse proportion current generator 451 can receive the inverse proportion current from a separate inverse proportion current source (not shown).

The second square current generator 452 includes a first saturation-mode NMOS transistor MN1. A voltage

$$\frac{2}{3} \times Vc$$

is applied to the gate terminal of the first NMOS transistor MN1, and a second square current related to a second term of Expression C is outputted through its drain terminal, The second constant current generator 453 generates a second constant current related to a third term of Expression G.

The second inverse proportion current (from 451), the second square current (from 452), and the second constant current (from 453) are summed (added together) at a second node N2, and the summation output is applied to the second current mirror 46 and output as the numerator current IC2.

The denominator current IC1 and the numerator current IC2 are applied respectively to terminals of the differential amplifier 49 as a bias current by the current mirrors comprised of the fifth NMOS transistor MN3 and the seventh NMOS transistor MN7, and of the third NMOS transistor MN3 and the sixth NMOS transistor MN6, respectively.

The differential amplifier 49 receives the differential input signal Vin (Vin+ and Vin−), and outputs a differential output signal Vout (Vout+ and Vout−). The differential amplifier 49 may include active resistors (loads, biased transistors MP2 and MP3) the resistance of which is determined by a bias voltage Vbias. In the differential amplifier 49, the voltage gain is expressed as the proportion of bias currents (denominator current IC1 and numerator current IC2) applied to the differential amplifier 49. For example, a differential pair that consists of an eighth NMOS transistor MN8 and a ninth NMOS transistor MN9 is biased by the numerator current IC2, And, a denominator current IC1 is applied to a pair of output resistors (a tenth NMOS transistor MN10 and an eleventh NMOS transistor MN11). The voltage at ach output resistor (the tenth NMOS transistor NM10 and the eleventh NMOS transistor NM11) is the reciprocal of the voltage gain of the small signal, and a resistance of the output resistor NM10 and NM11 is much smaller than the resistance of output resistors of a sixth PMOS transistor MP6 and a seventh PMQS transistor MP7. The voltage gain of the differential amplifier 49 is equal to a value that is generated by dividing a small signal voltage gain of the eighth NMOS transistor MN8 by the small signal voltage gain of the tenth NMOS transistor MN10 In addition, the small signal voltage gain of the eighth NMOS transistor MN8 is proportional to the square root of the numerator current IC2 and the small signal voltage gain of the tenth NMOS transistor NM10 is proportional to the square root of the denominator current IC10. Therefore, the voltage gain of the differential amplifier 49 is proportional to

$$\sqrt{\frac{IC 2}{IC 1}} .$$

### The square root does not effect the dB-linear features of the differential amplifier 49.

FIG. 5A is a graph illustrating dB-linear features of a conventional differential amplifier performing approximation by using a first order polynomial expression.

Referring to FIG. 5A, in a conventional differential amplifier that approximates by using a first order polynomial expression, the voltage gain is changed with dB-linear features responding to a control voltage in a low range, but the voltage gain is changed without dB-linear features responding to the control voltage in a high range.

FIG. 5B is a graph illustrating dB-linear features of a differential amplifier performing approximation by using a third order polynomial expression according to an exemplary embodiment of the present invention.

Referring to FIG. 5B, in differential amplifiers according to embodiments of the present invention that approximate by using a third order polynomial expression, the voltage gain is changed with dB-linear features regardless of the range of a control voltage.

In accordance with exemplary embodiments of the present invention, a method of varying the voltage gain, a variable voltage gain amplifier, and an automatic voltage gain control circuit can vary the voltage gain by using a third-order polynomial function as an exponential function.

In accordance with exemplary embodiments of the present invention, a method of varying a voltage gain, a variable voltage gain amplifier, and an automatic voltage gain control circuit can implement the third order polynomial expression using a complementary metal oxide semiconductor (CMOS) transistor by approximating the exponential function to a fraction where each of a denominator and a numerator is expressed as a third order polynomial expression and transforming the third order polynomial expression of the numerator and the denominator to an expression that includes an inversed first order polynomial term, a first order polynomial term, and a second order polynomial term.

In accordance with exemplary embodiments of the present invention, a to method of varying a voltage gain, a variable voltage gain amplifier, and an automatic voltage gain control circuit can have a variable voltage gain that is substantially dB-linear with a control voltage in a broad range.

While the exemplary embodiments of the present invention and their features have been described in detail, it should be understood that various changes, substitutions and alterations may be made herein without departing from the scope of the invention.

What is claimed is:

1. A method of varying a voltage gain, comprising:
approximating a variable voltage gain that is expressed as an exponential function of a control voltage to a fraction where each of the denominator and the numerator is expressed as a third order polynomial function of the control voltage;
generating a numerator current corresponding to the numerator and generating a denominator current corresponding to the denominator;
amplifying an input voltage with the variable voltage gain expressed as the fraction; and
generating an output voltage that is substantially dB-linear with the input voltage.

2. The method of claim 1, wherein generating the numerator current includes:
transforming the third order polynomial expression of the numerator to a function of the control voltage that includes an inversed first order polynomial term, a first order polynomial term, and a second order polynomial term; and
generating a current corresponding to each of the inversed first order polynomial term, the first order polynomial term, and the second order polynomial term.

3. The method of claim 1, wherein generating the denominator current includes:
transforming the third order polynomial expression of the denominator to a function of the control voltage that includes an inversed first order polynomial term, a first order polynomial term, and a second order polynomial term; and
generating a current corresponding to each of the inversed first order polynomial term, the first order polynomial term, and the second order polynomial term.

4. The method of claim 1, further comprising:
transforming the fraction where each of the denominator and the numerator is expressed as a third order polynomial function of the control voltage to a fraction as Expression 1.
$$Gain = Exp ( 2 aVc ) \approx \frac{1 / Vc + 3 / 8 a \times {( 1 + 2 / 3 a \times Vc )}^{2} + 5 / 8 a}{1 / Vc - 3 / 8 a \times {( 1 - 2 / 3 a \times Vc )}^{2} - 5 / 8 a} \qquad [ Expression 1 ]$$
where a denotes a coefficient ratio of the variable voltage gain, and Vc denotes the control voltage.

5. The method of claim 4, wherein generating the numerator current includes:
generating a second inverse proportion current corresponding to a first term of the numerator by using an analog divider;
generating a second square current corresponding to a second term of the numerator by using a second metal oxide semiconductor (MOS) transistor; and
generating a second constant current corresponding to a third term of the numerator by using a second current source.

6. The method of claim 5, wherein generating the denominator current includes:
generating a first inverse proportion current corresponding to a first term of the denominator by using an analog divider;
generating a first square current corresponding to a second term of the to denominator by using a first metal oxide semiconductor (MOS) transistor; and
generating a first constant current corresponding to a third term of the denominator by using a first current source.

7. The method of claim 6, wherein:
generating the denominator current further includes subtracting the sum of the first square current and the first constant current from the first inverse proportion current from; and
generating the numerator current includes summing the second inverse proportion current, the second square current, and the second constant current.

8. The method of claim 1, wherein the input voltage is a differential signal and the output voltage is a differentiate signal.

9. A variable voltage gain amplifier wherein a variable voltage gain that is expressed as an exponential function of a control voltage is approximated to a fraction where each of the denominator and the numerator is expressed as a third order polynomial function of the control voltage, the amplifier comprising:
a denominator current source configured to generate a denominator current corresponding to the denominator;
a numerator current source configured to generate a numerator current corresponding to the numerator; and
an amplifier configured to amplify the input voltage with the variable to voltage gain expressed as the fraction.

10. The variable voltage gain amplifier of claim 9, wherein the input voltage is a differential voltage and wherein the amplifier is a differential amplifier configured to generate an output voltage that is substantially dB-linear with the input voltage.

11. The variable voltage gain amplifier of claim 9, wherein, when the third order polynomial expression of each of the numerator and the denominator is transformed to a function of the control voltage that includes an inversed first order polynomial term, a first order polynomial term and a second order polynomial term,
the numerator current source and the denominator current source generate a current corresponding to each of the inversed first order polynomial term, the first order polynomial term and the second order polynomial term.

12. The variable voltage gain amplifier of claim 11, wherein the denominator current source and the numerator current source generate the denominator current and the numerator current corresponding respectively to the denominator and the numerator in Expression 1.
$$Gain = Exp ( 2 aVc ) \approx \frac{1 / Vc + 3 / 8 a \times {( 1 + 2 / 3 a \times Vc )}^{2} + 5 / 8 a}{1 / Vc - 3 / 8 a \times {( 1 - 2 / 3 a \times Vc )}^{2} - 5 / 8 a} \qquad [ Expression 1 ]$$
where a denotes a coefficient ratio of the variable voltage gain, and Vc denotes the control voltage.

13. The variable voltage gain amplifier of claim 12, wherein the denominator current source includes:
a first inverse proportion current generator configured to generate a first inverse proportion current corresponding to the first term of the denominator in expression 1;
a first square current generator configured to generate a first square current corresponding to the second term of the denominator in expression a;
a first constant current generator configured to generate a first constant current corresponding to the third term of the denominator in expression 1; and
a first summation unit configured to sum the first square current and the first constant current, to subtract the sum from the first inverse proportion current, and configured to generate the denominator current.

14. The variable voltage gain amplifier of claim 13, wherein the first inverse proportion current generator includes an analog divider that receives the control voltage, and outputs a current that has an inversed value of the control voltage.

15. The variable voltage gain amplifier of claim 13, wherein the first square current generator includes a PMOS transistor wherein a voltage of ⅔×Vc is applied to its gate terminal, a supply voltage is applied to its source terminal and the first square current is outputted through its drain terminal, and the PMOS transistor satisfies Expression 2.
$$Kp = \frac{3 / 8 a}{{( Vdd - Vth )}^{2}} , a = \frac{1}{Vdd - Vth} \qquad [ Expression 2 ]$$
where Kp denotes a process parameter of the PMOS transistor, Vth denotes the threshold voltage of the PMOS transistor, Vdd denotes the supply voltage, and a denotes a coefficient ratio of the variable voltage gain.

16. The variable voltage gain amplifier of claim 12, wherein the numerator current source includes:
a second inverse proportion current generator configured to generate a second inverse proportion current corresponding to the first term of the numerator in Expression 1;
a second square current generator configured to generate a second square current corresponding to the second term of the numerator in Expression 1;
a second constant current generator configured to generate a second constant current corresponding to the third term of the numerator in Expression 1; and
a second summation unit configured to sum the second inverse proportion current, the second square current, and the second constant current, and configured to generate the numerator current.

17. The variable voltage gain amplifier of claim 16, wherein the second square current generator includes a NMOS transistor where a voltage of ⅔×Vc is applied to its gate terminal, a supply voltage is applied to its source terminal and the second square current is outputted through its drain terminal, and the NMOS transistor satisfies Expression 3.
$$Kn = \frac{3 / 8 a}{{( - Vss - Vth )}^{2}} , a = \frac{1}{( - Vss - Vth )} \qquad [ Expression 3 ]$$
where Kn denotes a process parameter of the NMOS transistor, Vth denotes the threshold voltage of the NMOS transistor, Vss denotes the supply voltage, and a denotes a coefficient ratio of the variable voltage gain.

18. The variable voltage gain amplifier of claim 10, wherein each of the input voltage and the output voltage is a differential signal.

19. The variable voltage gain amplifier of claim 15, wherein the differential amplifier includes:
a first differentiate pair of diode-connected MOS transistor configured to be biased by the denominator current, and
a second differentiate pair of MOS transistors configured to receive the input voltage at their gate terminals, configured to be biased by the numerator current, and each configured to be coupled to one of the first differential pair of MOS transistors at their drain terminals, and configured to output the output to voltage at their drain terminals.

20. An automatic voltage gain control circuit, comprising:
a variable voltage gain amplifier configured to generate an output voltage from an input voltage, and having a variable voltage gain controlled by a control voltage, wherein the variable voltage gain is expressed as an exponential function of the control voltage and is approximated to a fraction where each of a denominator and a numerator is a third order polynomial function of the control voltage, wherein the variable voltage gain amplifier includes:
a denominator current source configured to generate a denominator current corresponding to the denominator;
a numerator current source configured to generate a numerator current corresponding to the numerator; and
a differential amplifier configured to amplify the input voltage with the variable voltage gain, and configured to generate an output voltage that is substantially dB-linear with the input voltage;
an amplitude detector configured to detect the amplitude of the output voltage; and
a differential amplifier configured to compare the detected amplitude of the output voltage with an amplitude of a reference signal, and configured to generate the control voltage.

21. The automatic voltage gain control circuit of claim 17, wherein, when the third order polynomial expression of the numerator and the denominator is approximated by a function of the control voltage that includes an inversed first order polynomial term, a first order polynomial term, and a second order polynomial term,
wherein each of the numerator current generator and the denominator current generator generate currents corresponding to each's respective inversed first order polynomial term, order polynomial term, and second order polynomial term.

22. The automatic voltage gain control circuit of claim 18, wherein the denominator current source and the numerator current source respectively generate the denominator current and the numerator current corresponding to the denominator and the numerator in Expression 1
$$Gain = Exp ( 2 aVc ) \approx \frac{1 / Vc + 3 / 8 a \times {( 1 + 2 / 3 a \times Vc )}^{2} + 5 / 8 a}{1 / Vc - 3 / 8 a \times {( 1 - 2 / 3 a \times Vc )}^{2} - 5 / 8 a} \qquad [ Expression 1 ]$$
where a denotes a coefficient ratio of the variable voltage gain, and Vc denotes the control voltage.

23. The automatic voltage gain control circuit of claim 19, wherein the denominator current source includes:
a first inverse proportion current generator configured to generate a first inverse proportion current corresponding to a first term of the denominator in Expression 1;
a first square current generator configured to generate a first square current corresponding to a second term of the denominator in Expression 1;
a first constant current generator configured to generate a first constant current corresponding to a third term of the denominator in Expression 1; and
a first summation unit configured to sum the first square current and the first constant current, and to subtract the sum from the first inverse proportion current, and configured to generate the denominator current.

24. The automatic voltage gain control circuit of claim 20, wherein the first square current generator includes a PMOS transistor where a voltage of ⅔×Vc is applied to its gate terminal, a supply voltage is applied at its source terminal, and the first square current is outputted through its drain terminal, and the PMOS transistor satisfies Expression 2.
$$Kp = \frac{3 / 8 a}{{( Vdd - Vth )}^{2}} , a = \frac{1}{Vdd - Vth} \qquad [ Expression 2 ]$$
where Kp denotes a process parameter of the PMOS transistor, Vth denotes the threshold voltage of the PMQS transistor, Vdd denotes the supply voltage, and a denotes a coefficient ratio of the variable voltage gain.

25. The automatic voltage gain control circuit of claim 19, wherein the numerator current source includes:
a second inverse proportion current generator configured to generate a second inverse proportion current corresponding to a first term of the numerator in Expression 1;
a second square current generator configured to generate a second square current corresponding to a second term of the numerator in Expression 1;
a second constant current generator configured to generate a second constant current corresponding to a third term of the numerator in Expression 1 and
a second summation unit configured to sum the second inverse proportion current, the second square current, and the second constant current, and configured to generate the numerator current.

26. The automatic voltage gain control circuit of claim 23, wherein the second square current generator includes a NMOS transistor where a voltage of ⅔×Vc is applied at its gate terminal, a supply voltage is applied at its 1 source terminal and the second square current is outputted at its drain terminal, and the NMOS transistor satisfies Expression 3.
$$Kn = \frac{3 / 8 a}{{( - Vss - Vth )}^{2}} , a = \frac{1}{( - Vss - Vth )} \qquad [ Expression 3 ]$$
where Kn, denotes a process parameter of the NMOS transistor, Vth denotes the threshold voltage of the NMOS transistor, Vss denotes the supply voltage and a denotes a coefficient ratio of the variable voltage gain.

27. The automatic voltage gain control circuit of claim 26, wherein the differential amplifier includes:
a first MOS transistor differential pair configured to be diode-connected respectively and configured to be biased by the denominator current; and
a second MOS transistor differentiate pair configured to receive the input voltage at their gate terminals, configured to be biased by the numerator current, configured to be coupled to the first MOS transistor differential pair at their respective drain terminates, and configured to output the output voltage through the drain terminal.

28. A variable voltage gain amplifier, comprising:
a denominator current source configured to generate a denominator current corresponding to a denominator of a third order polynomial function of a control voltage;
a numerator current source configured to generate a numerator current corresponding to the numerator current corresponding to a numerator of a third order polynomial function of the control voltage; and
an amplifier configured to amplify the input voltage with the variable voltage gain being based upon the ratio of the numerator current divided by the denominator current.

29. The variable voltage gain amplifier of claim 28, wherein the denominator current source includes,
a first inverse proportion current generator configured to generate a first in inverse proportion current corresponding to a first term of the denominator;
a first square current generator configured to generate a first square current corresponding to a second term of the denominator;
a first constant current generator configured to generate a first constant current corresponding to a third term of the denominator; and
a first summation unit configured to generate the denominator current by summing the first square current and the first constant current, and subtracting the sum from the first inverse proportion current.

30. The variable voltage gain amplifier of claim 29, wherein the numerator current source includes:
a second inverse proportion current generator configured to generate a second inverse proportion current corresponding to a first term of the numerator;
a second square current generator configured to generate a second square current corresponding to a second term of the numerator;
a second constant current generator configured to generate a second constant current corresponding to a third term of the numerator; and
a second summation unit configured to generate the numerator current by summing the second inverse proportion current, the second square current, and the second constant current.
